(19) United States
(12) Patent Application Publication
(10) Pub. No.: US 2006/0281223 A1
(43) Pub. Date: Dec. 14, 2006

(54) Packaging method and package using the same

(75) Inventors: Chien Liu, Kaohsiung City (TW); Chih-Ming Chung, Kaohsiung City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Accton Technology Corporation

(21) Appl. No.: 11/322,676

(22) Filed: Dec. 30, 2005

(30) Foreign Application Priority Data
Jun. 8, 2005 (TW) 94118965

(51) Int. Cl. H01L 21/58

(52) U.S. Cl. 438/108; 438/615; 438/113

(57) ABSTRACT

The invention achieves the above-identified object by providing a packaging, comprising steps of: (a) providing an integrated circuit unit having an active surface, a plurality of bumps disposed thereon; (b) providing a substrate having a first surface and a second surface, a plurality of pads disposed on the first surface, a metal layer formed on the second surface; (c) forming an integrated circuit assembly by connecting the bumps and pads; and (d) forming a plurality of metallic pieces by etching the metal layer.

This application claims the benefit of Taiwan Application Serial No. 094118965, filed Jun. 8, 2005, the subject matter of which is incorporated herein by reference.

### BACKGROUND OF THE INVENTION

1. Field of the Invention

The invention relates in general to a packaging method and a package using the same, and more particularly to a packaging method using a coreless substrate and a package having a coreless substrate

2. Description of the Related Art

Referring to FIG.1, a cross-sectional view of a conventional flip-chip package. The conventional flip-chip package is a substrate and a flip chip both of which are jointed by welding. The conventional flip chip package includes a die 10 and a substrate 20. The substrate 20 has several patterned wiring layers 24 (such as 24a, 24b, 24c), several insulation layers 26 (such as 26a, 26b, 26c), and a core layer 40. Wiring layers 24 and insulation layers 26 are alternately stacked on the core layer 40 and covers the through hole 46 to construct a predetermined interconnecting wiring structure. Several plugs 36 penetrating the insulation layers 24 electrically connect the respective wiring layers 24. In general, two types of plugs 36 is classified into via plug 36a and plating through hole (PTH) plug 36b.

In addition, the substrate 20 includes several bump pad 30 for connecting the bumps 16 oh the die 10 and several ball pads 34 on the bottom surface. The bump pads 30 are individually electrically connected to ball pads 34 through the interconnecting wiring structure. Besides, the substrate 20 further includes a under ball metallurgy (UBM) 40 and solder ball 44 for connecting another substrate, such as printed circuit board. However, the substrate including the core layer is thick, and the size of the package including this kind of substrate will be also increased. The force of the core layer 40 which is much thicker than wiring layer and insulation layer will be greatly reduced after forming the through hole, so that of the core layer 40 has to remains thick for providing sufficient support. It is therefore difficult to reduce the thickness of the substrate and also to shrink the size of the package. On the other hand, the step of forming solder ball is performed by putting the whole package in the reflow oven and reflowing cubic metal at high temperature for long time, so that the conventional package, including the substrate and the chip, is subject to damage by heat. It deteriorates the quality and shortens lifetime of the product.

### SUMMARY OF THE INVENTION

In view of the foregoing, it is an object of the present invention to provide a method for packaging and a package using the same. It is the metal layer for supporting conductive layers and insulation films in the preceding steps that will be etched as many metallic pieces in the after step. Thus, the complicated and harmful steps for forming solder ball can be omitted. In addition, the size and thickness of the package will be much smaller and thinner if a coreless substrate is applied in the package.

The invention achieves the above-identified object by providing a packaging, comprising steps of: (a) providing an integrated circuit unit having an active surface, a plurality of bumps disposed thereon; (b) providing a substrate having a first surface and a second surface, a plurality of pads disposed on the first surface, a metal layer formed on the second surface; (c) forming an integrated circuit assembly by connecting the bumps and pads; and (d) forming a plurality of metallic pieces by etching the metal layer.

It is another object of the invention to provide a package, comprising: a coreless substrate having a first surface and a second surface, a plurality of metallic pillar disposed on the second surface, wherein the metallic pillars comprise copper; and an integrated circuit unit electrically connected to the substrate and positioned on the first surface.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG.1 is a cross-sectional view of a conventional flip-chip package;

FIGS. 2A˜2E illustrate a packaging method according to the embodiment one of the present invention.

FIGS. 3A˜3E are top view illustrating the wafer level chip size packaging method according to the embodiment two of the invention.

FIGS. 4A˜4C illustrates the packaging method according to embodiment three of the present invention.

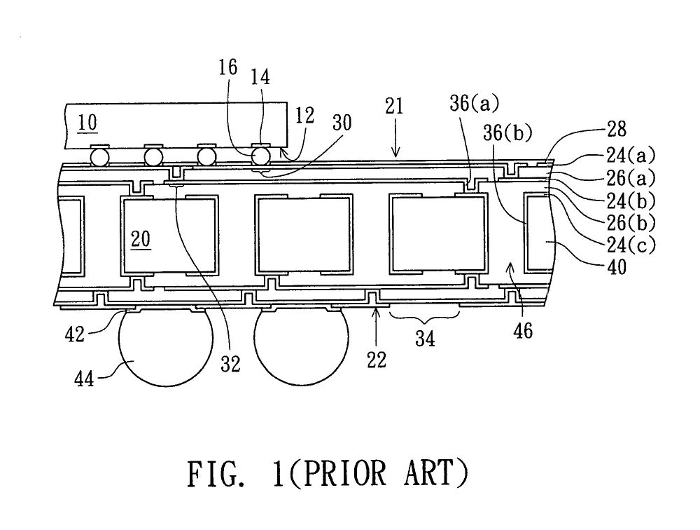

### DETAILED DESCRIPTION OF THE INVENTION

The present invention now will be described more fully hereinafter with reference to the accompanying drawings, in which preferred embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art.

The present invention is provided a packaging method and a package structure using the same, in which metallic pieces for electrically connecting are formed by etching a metal layer disposed under the substrate. It allows to not only reduce the thickness of the substrate but also simplify the manufacturing procedure and saving the cost.

Embodiment One

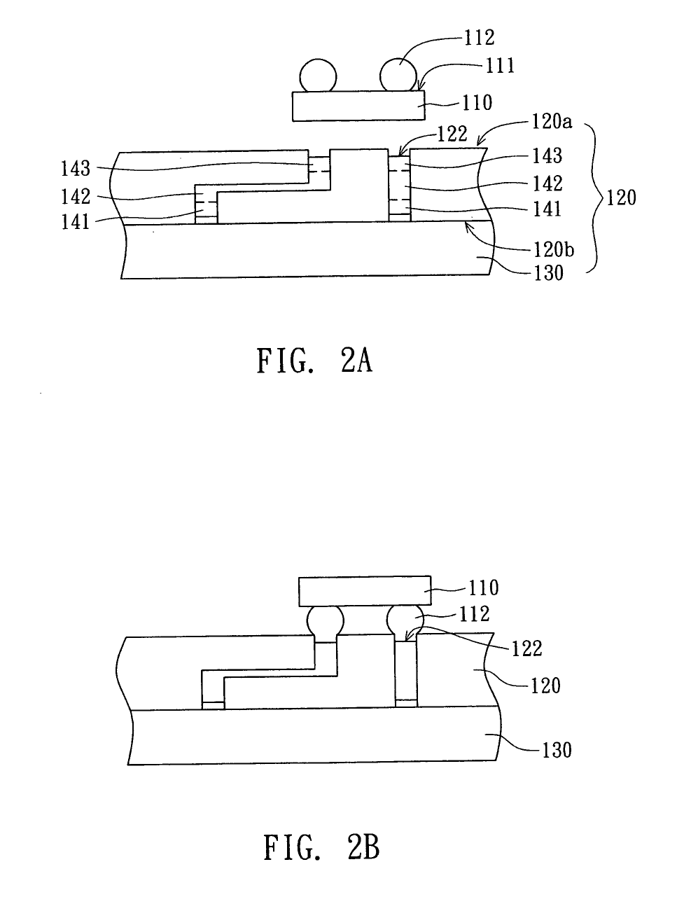

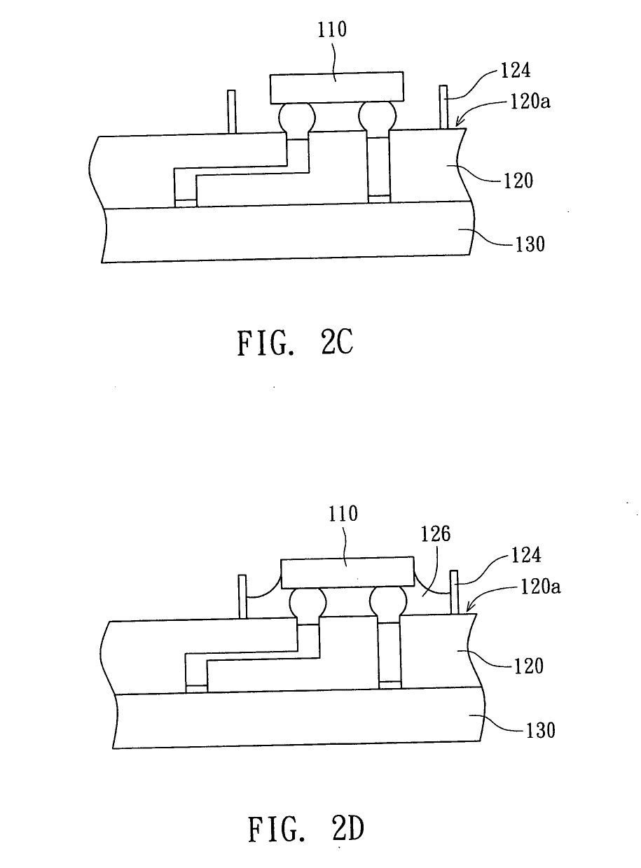

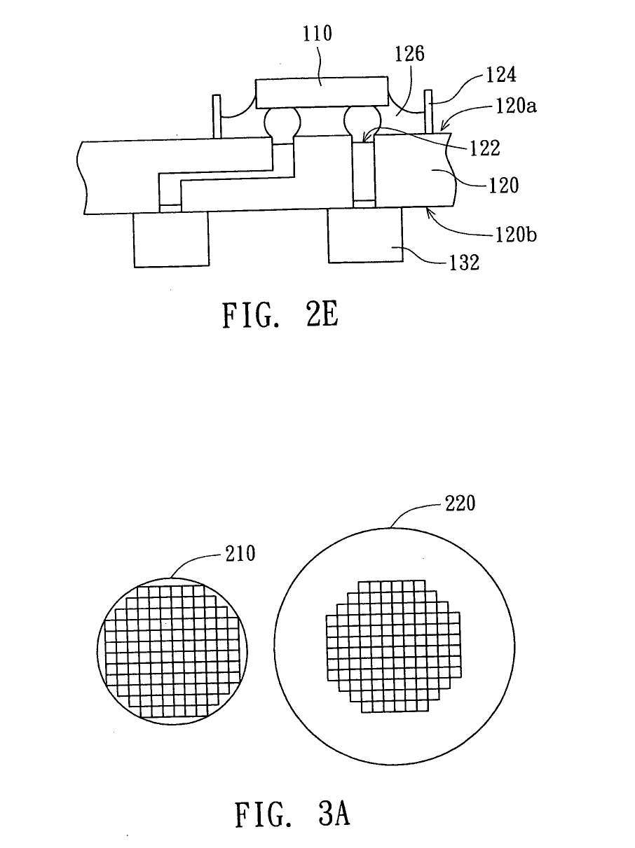

Referring to FIGS. 2A˜2E, these illustrate a packaging method according to the embodiment one of the present invention. It is noted that the substrate completely shown in FIG. 2A will be simplified in FIG. 2B˜2E to make the whole package clear. The packaging method of the present embodiment includes following steps. Firstly, an integrated circuit unit 110 and a substrate 120 are provided as shown in FIG. 2A. The integrated circuit unit 110, such as die, semiconductor unit or wafer, has an active surface 111, and several bumps 112 are disposed on the active surface 111. On the other hand, the substrate 120 has a first surface 120a and a second surface 120b. Several pads 133 are disposed on the first surface 120a and relative to bumps, and a metal layer 130 is formed on the second surface 120b. Preferably, the metal layer 130 comprises copper.

Then, the integrated circuit unit 110 is flipped so as to allow bumps 112 to be opposite to pads 122, and bumps 112 is connected to the pads 122, i.e. by welding, to form an integrated circuit assembly as shown in FIG. 2B. If the integrated circuit units 110 are several unpackaged and singulated dies, they will be respectively put on the substrate 120 so as to allow bumps 112 to be opposite to pads 122, and then dies and the substrate 120 are connected to each other by welding bumps 112 into pads 122.

Next, a dam 124 is formed on the first surface 120a of the substrate, and positioned around the integrated circuit unit 110 as shown in FIG. 2C. Afterward, an underfill 126, such as liquid adhesive, is added between the integrated circuit unit 110 and substrate 120, and limited within the dam 124 as shown in FIG. 2D.

In addition, several metallic pieces 132 are formed by etching the metal layer 130. For example the metallic pieces 132 etched from the metal layer 130 including copper are several copper pillars as shown in FIG. 2E. The conductivity of the copper pillar is better than the conventional solder ball. Also, the complicated and harmful steps for forming solder ball can be omitted. The step of forming solder ball is performed by putting the whole package in the reflow oven and reflowing cubic metal at high temperature, so that the conventional package is subject to damage by heat. The package of the present invention, whose metallic pieces are made by etching the metal layer instead, therefore owns good quality and elongated lifetime. The packaging method preferably further includes a step of forming a protective layer, such as an organic solderability preservative (OSP), on the metallic. It prevents the metallic pieces from oxidation, so allows to avoid the disconnect problem between metallic pieces and another substrate in the process of next packaging level.

Finally, the integrated circuit assembly is divided into several packages by sawing.

It is noted that the substrate 120 can be either a general substrate with a core layer or a coreless substrate. The substrate 120 is preferably a coreless substrate because the package using a coreless substrate is much thinner that conventional one. Referring to FIG. 2A, the coreless substrate 120 is an electrical interconnecting structure consists of several complex layers, each of which includes a substrate without a core layer and a predetermined wiring layout formed thereon. Every two conductive wiring layer are insulated by one insulation layer, and electrically connected to each other thorough a filled via-hole embedded in the insulation layer. The substrate is preferably the metal layer 130 for supporting several thin and soft conductive layers and insulation films from being broken.

The method for forming electrical interconnecting structure is stated below. Referring to FIG. 2A, a first conductive layer 141 is formed on the metal layer 130 for developing the wire upward, and an insulation film is formed thereon. Next, a via-hole is formed in the insulation film, and then a second conductive layer 142 is formed on the first conductive layer 141 and insulation film by sputtering, depositing, physically or chemically method. After the second conductive layer 142 is patterned, another insulation film is formed thereon. The second conductive layer 142 extends horizontally and fans in to area so as to be opposite to the bumps of the die, and is electrically connected to the first conductive layer 141 through the filled via-hole. In the same way, a third conductive layer 143 is further formed on the second conductive layer 142 and exposed on the first surface 120a of the substrate as a pad, which is made to be opposite to the bumps.

In particular, it is the metal layer for supporting conductive layers and insulation films in the preceding steps that will be etched as many metallic pieces in the after step. Thus, the method of the present embodiment has simplified process, which decreases the cost, and the package to which applies the method owns the substrate of greatly decreased thickness.

Referring to FIG. 2E, it is a cross sectional view of the package according to embodiment one of the present invention. The package of the present embodiment includes a coreless substrate 120 and an integrated circuit 110. The coreless substrate 120 has a first surface 120a and a second surface 120b; several pads 122 are exposed on the first surface 120a, and several metallic pieces are exposed on the second surface 120b. The integrated circuit unit 110 is disposed on the first surface 120a, and electrically connected to the substrate 120. The integrated circuit 110 including several bumps 112 is correspondingly connected to the pads 122 on the first surface 120a of the substrate, the package stated above is therefore classified as a flipped-chip package. The package further includes underfill 126 filled the space existed between the integrated circuit unit 110 and the substrate 120. Compared with the conventional package, the package using the coreless substrate is much thinner and smaller so as to allow the whole package or the apparatus containing thereof to be miniaturized.

Embodiment Two

It is the integrated circuit unit of the present embodiment that differs from that of the embodiment one. The whole wafer is directly applied to the method for packaging in the present embodiment, as so called wafer level chip size package (WLCSP). Besides, a coreless substrate, whose interconnecting structure is easily made to fit in with the wafer, is preferably applied in the WLCSP method, because the process for manufacturing the coreless substrate is substantially the same as that for the wafer.

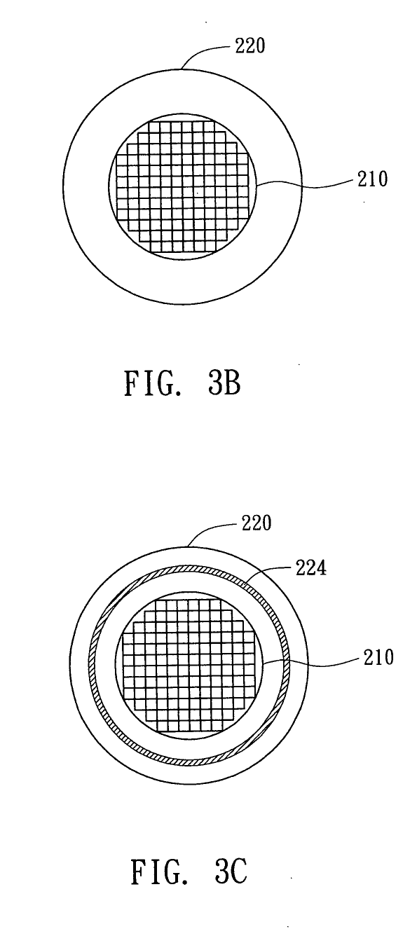

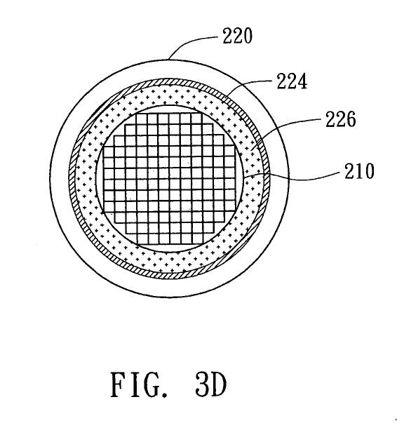

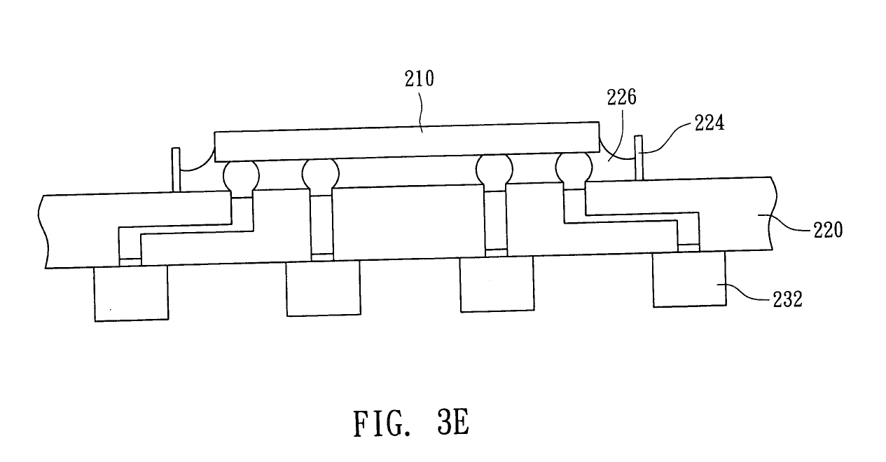

FIGS. 3A˜3E are top view illustrating the wafer level chip size packaging method according to the embodiment two of the invention. Firstly, a wafer 210 and a coreless substrate 220, both of which have similar size and electrically interconnect structure matching each other are provided as shown in FIG. 3A. Next, the whole wafer 210 is flipped and then connected to the coreless substrate 220 as an integrated circuit assembly as shown in FIG. 3B. The connection of the wafer and the coreless substrate is preferably preformed by welding. Then, a dam 224 is disposed on the coreless substrate 220 and positioned around the wafer 210 as shown in FIG. 3C. Afterward, an underfill 226, such as liquid adhesive, is added between the wafer 210 and the coreless substrate 220 and limited within the dam 224 as shown in FIG. 3D. Next, several metallic pieces 132, such as copper pillars, are formed by etching the metal layer as shown in FIG. 3E. Finally, the integrated circuit assembly is divided into several packages by sawing. The WLCSP method of the present embodiment not only owns advantages stated in the preceding embodiment but also can greatly increase the productivity

Embodiment Three

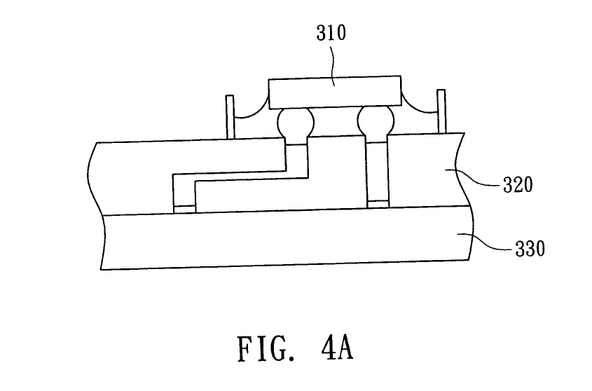

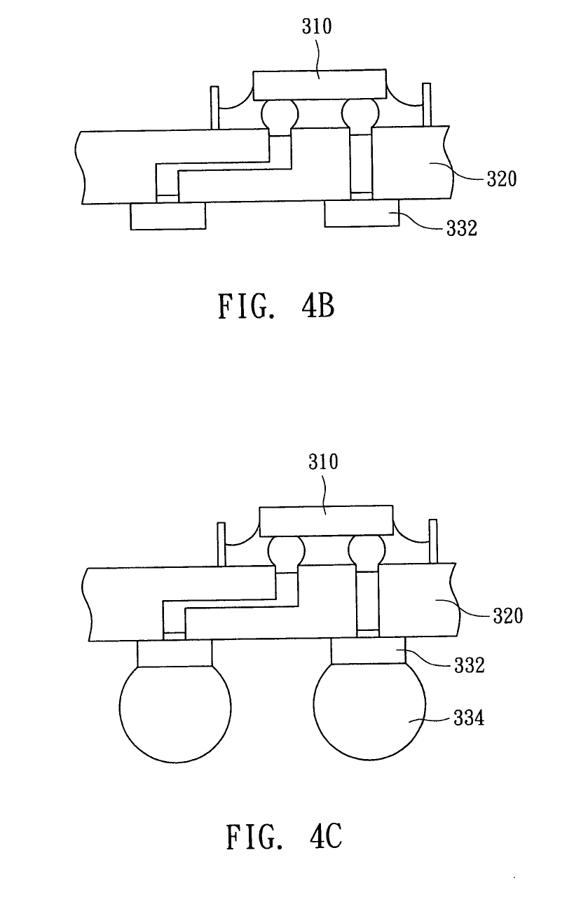

It is the metallic piece of the present embodiment that differs from that of the embodiment one, but the other elements remains the same so as to omit the description thereof. FIGS. 4A˜4C illustrates the packaging method according to embodiment three of the present invention. Firstly, the integrate circuit assembly including an integrated circuit unit 310 and a substrate 320 as shown in FIG. 4A. Next, several metallic piece, such as ball pads 332, are formed by etching the metal layer 330 as shown in FIG. 4B. The metal layer preferably including copper, and ball pads are preferably are several copper pads. Finally, several solder balls 334 are correspondingly formed on the ball pads 332 as shown in FIG. 4C.

As described hereinbefore, the packaging method and package using the same has many advantages. It is the metal layer for supporting conductive layers and insulation films in the preceding steps that will be etched as many metallic pieces in the after step. Thus, the method of the present embodiment has simplified process, which decreases the cost, and the package to which applies the method owns the substrate of greatly decreased thickness. Further, it not only provides support in the manufacturing process but also reduces the thickness of the finished package or the apparatus containing the package. Also, the complicated and harmful steps for forming solder ball can be omitted. The step of forming solder ball is performed by putting the whole package in the reflow oven and reflowing cubic metal at high temperature, so that the conventional package is subject to damage by heat. The conductivity of the copper pillar is better than the conventional solder ball. Thus, The package of the present invention, whose metallic pieces are made by etching the metal layer instead, owns good quality and elongated lifetime. In addition, the size and thickness of the package will be much smaller and thinner if a coreless substrate is applied in the package.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A packing method, comprising:
providing an integrated circuit unit having an active surface, a plurality of bumps disposed thereon;
providing a substrate having a first surface and a second surface, a plurality of pads disposed on the first surface, a metal layer formed on the second surface;
forming an integrated circuit assembly by connecting the bumps and pads; and
forming a plurality of metallic pieces by etching the metal layer.

2. The method according to claim 1, wherein the metal layer comprises copper.

3. The method according to claim 1, wherein the metallic pieces are a plurality of ball pads.

4. The method according to claim 3 after step of forming the metallic pieces further comprising
forming a plurality of solder ball on the ball pads.

5. The method according to claim 1, wherein the metallic pieces are a plurality of copper pillars.

6. The method according to claim 1, wherein the substrate is a coreless substrate.

7. The method according to claim 1 after step of connecting the bumps and the pads further comprising:
forming a dam on the first surface of the substrate and around the integrated circuit unit.

8. The method according to claim 7 after step of forming the dam further comprising:
adding an underfill between the integrated device and the substrate, wherein the underfill is limited in the dam.

9. The method according to claim 1 after step of forming the metallic pieces further comprising:
forming a protective layer on the metallic pieces.

10. The method according to claim 9, wherein the protective layer is an organic solderability preservative (OSP).

11. The method according to claim 11 after forming the metallic pieces further comprising:
sawing the integrated circuit assembly.

12. The method according to claim 1, wherein the integrated circuit unit is a die.

13. The method according to claim 1, wherein the integrated circuit unit is a wafer.

14. The method according to claim 1, wherein the integrated circuit assembly is a wafer level chip size package (WLCSP).
